(19) United States
(12) Patent Application Publication
(10) Pub. No.: US 2014/0313648 A1
(43) Pub. Date: Oct. 23, 2014

(54) MOUNTING APPARATUS FOR TOUCH PAD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: RONG YANG, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/085,975

(22) Filed: Nov. 21, 2013

(30) Foreign Application Priority Data
Apr. 22, 2013 (CN) 2013101397945

(51) Int. Cl. H05K 5/02

(52) U.S. Cl. CPC H05K 5/0217
USPC 361/679.01

(57) ABSTRACT

An electronic device includes an enclosure, a mounting member, and a touch pad. A number of mounting posts protrudes from an inner surface of the enclosure. The mounting member includes a mounting plate and a plurality of tabs extending from the mounting plate. Each of the plurality of tabs defines a mounting hole. The touch pad is attached to the mounting plate. Each of the plurality of posts is inserted through one of the plurality of mounting holes thereby mounting the touch pad to the enclosure.

### REFERENCE TO RELATED APPLICATIONS

This application claims all benefits accruing under 35 U.S.C. §119 from China Patent Application No. 201310139794.5 filed on Apr. 22, 2013 in the State Intellectual Property Office of China, the contents of the China Application are hereby incorporated by reference.

### BACKGROUND

1. Technical Field

The present disclosure generally relates to mounting apparatuses, and particularly relates to mounting apparatuses for a touch pad.

2. Description of Related Art

A touch pad is typically mounted on an electronic device, such as a notebook computer. When a touch-sensitive surface of the touchpad is touched, a cursor on a screen of the notebook computer moves or an item displayed on the screen can be selected. Generally, the notebook computer includes an enclosure and the touch pad is mounted to an inner surface of the enclosure by screws. However, mounting the touch pad with screws may be complicated and time-consuming.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device including a touch pad.

FIG. 2 is similar to FIG. 1, but viewed from another aspect.

FIG. 3 is an assembled view of the electronic device of FIG. 2.

FIG. 4 is similar to FIG. 3, but viewed from another aspect.

FIG. 5 is similar to FIG. 3, showing the mounting member in a locked position.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

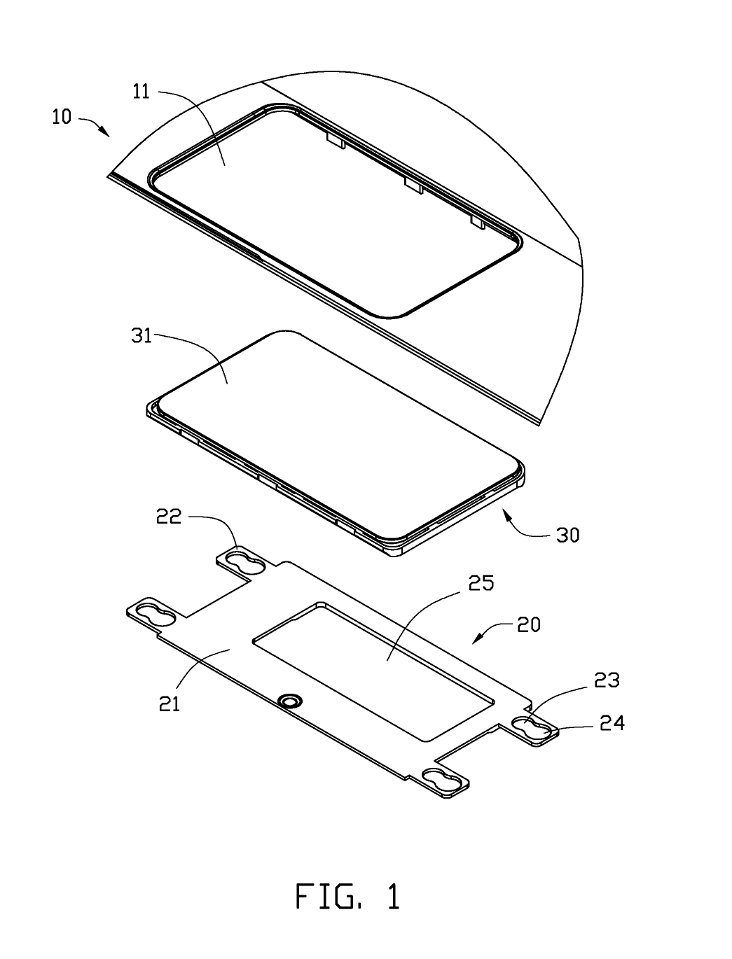

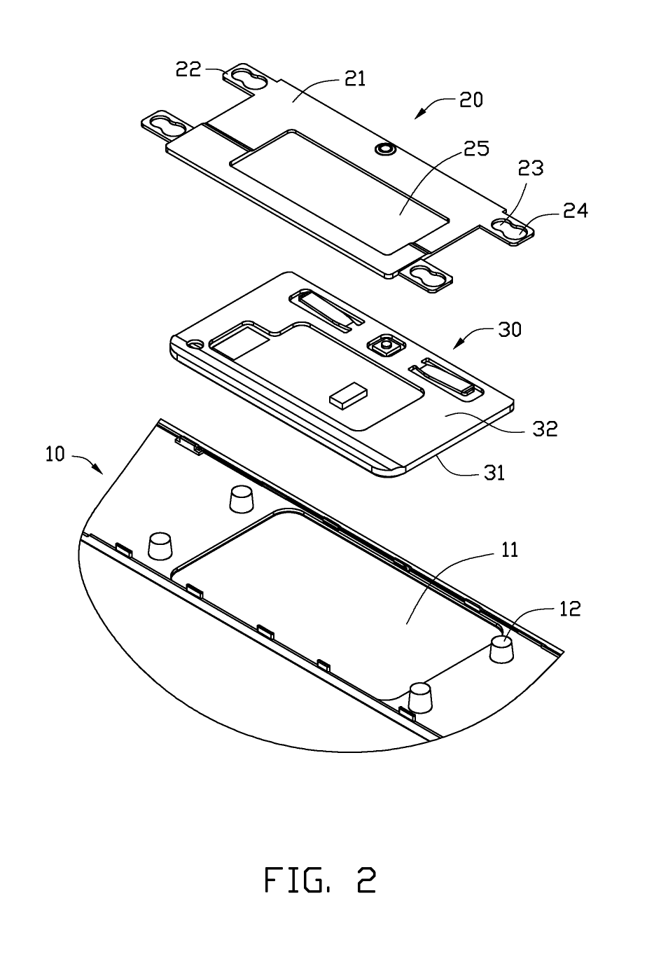

FIGS. 1 and 2 show an embodiment of an electronic device. The electronic device includes an enclosure 10, a mounting member 20, and a touch pad 30.

A plurality of mounting posts 12 protrudes from an inner surface of the enclosure 10. A diameter of a top end of the mounting post 12 is smaller than that of a bottom end of the mounting post 12.

The enclosure 10 defines an opening 11. The plurality of mounting posts 12 surrounds the opening 11.

The mounting member 20 includes a mounting plate 21 and a plurality of tabs 22. The plurality of tabs 22 extends from the mounting plate 21. In some embodiments, each of the plurality of tabs 22 is substantially rectangular. The mounting plate 21 is substantially rectangular.

Each of the plurality of tabs 22 defines a mounting hole 23 and an installation hole 24. The mounting plate 21 defines a through opening 25. The installation hole 24 communicates with the mounting hole 23. A diameter of the installation hole 24 is greater than that of the mounting hole 23.

The touch pad 30 includes a touch-sensitive surface 31 and a rear surface 32 opposite to the touch-sensitive surface 31.

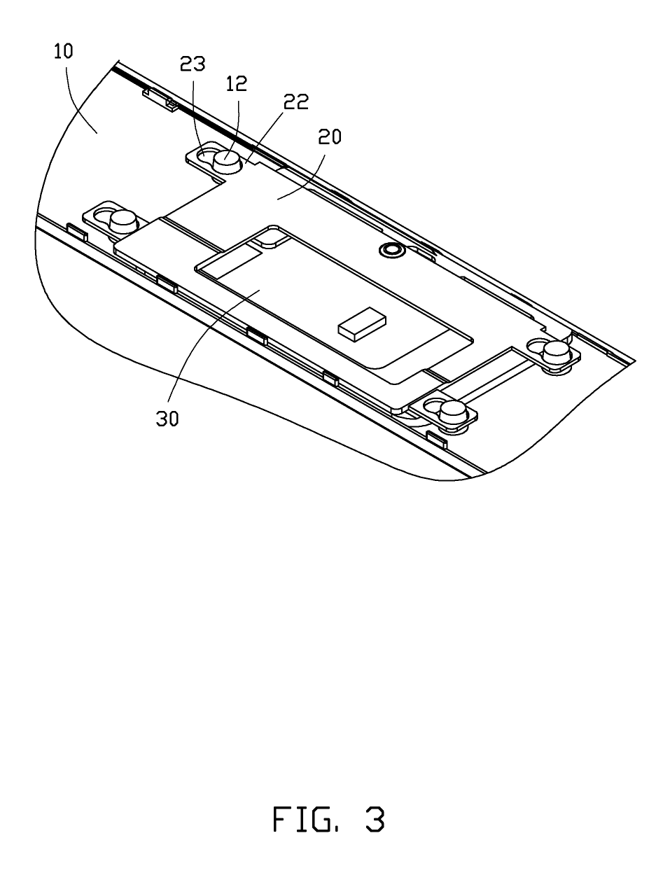

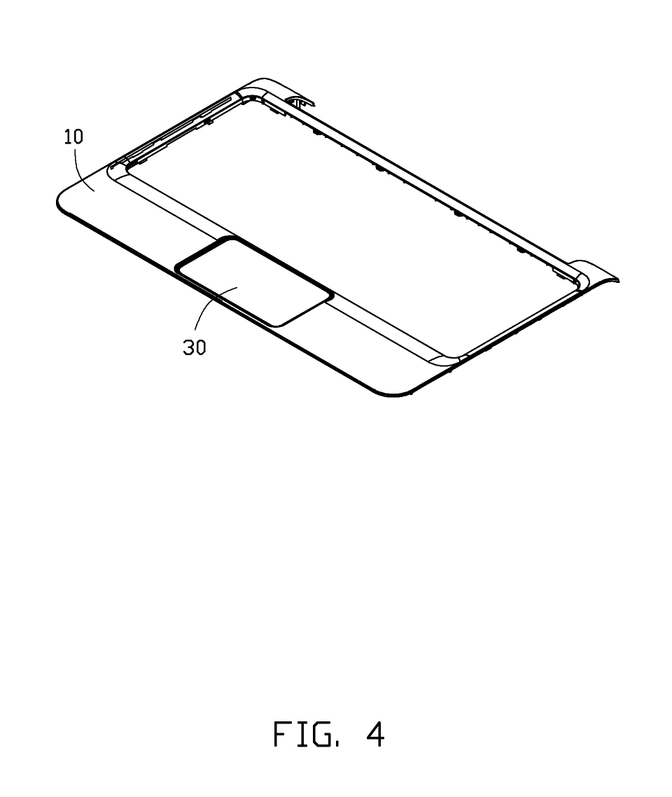

FIGS. 3-5 show that in assembly, the rear surface 32 of the touch pad 30 is glued with the mounting plate 21. A portion of the rear surface 32 of the touch pad 30 is exposed by the though hole 25 of the mounting plate 21. The touch-sensitive surface 31 of the touch pad 30 is touchable through the opening 11 of the enclosure 10.

The mounting member 20 is movable between a locked position and a unlocked position.

FIG. 3 shows that the mounting member 20 is located in the unlocked position. Each of the plurality of posts 12 is received in one of the plurality of installation holes 24. The touch pad 30 can be moved away from the enclosure 10.

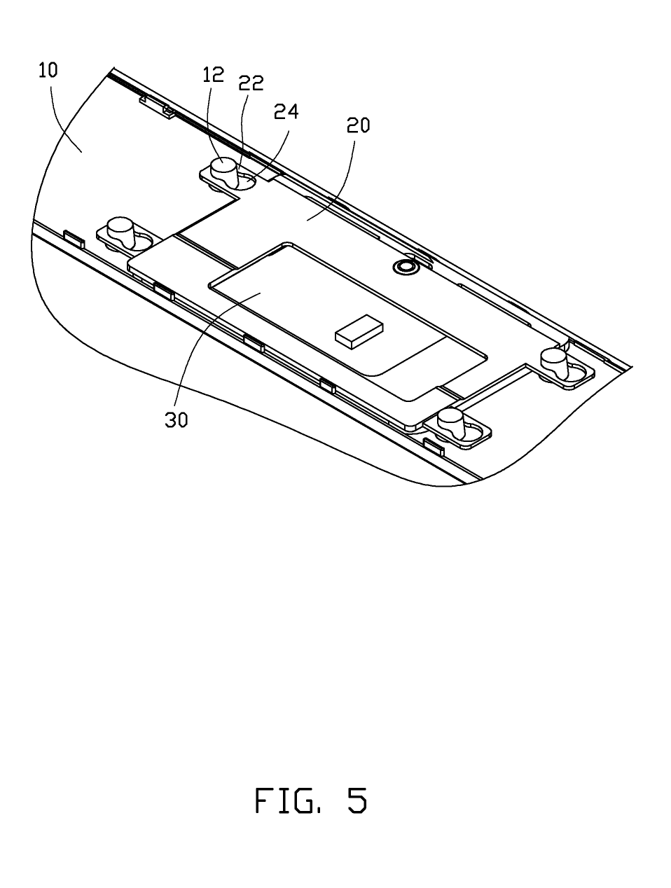

FIG. 5 shows that the mounting member 20 is located in the locked position. Each of the plurality of posts 12 is received in one of the plurality of mounting holes 24. The touch pad 30 is fixed in the electronic device.

When the mounting member 20 is moved in a first direction, the mounting member 20 is moved to the unlocked position and the mounting post 12 slides from the installation hole 24 to the mounting hole 23.

When the mounting member 20 is moved in a second direction opposite to the first second direction, the mounting member 20 is moved to the locked position and the mounting post 12 slides from the mounting hole 23 to the installation hole 24.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device, comprising:
an enclosure;
a plurality of mounting posts protruding from an inner surface of the enclosure;
a mounting member comprising a mounting plate and a plurality of tabs extending from the mounting plate, each of the plurality of tabs defining a mounting hole; and
a touch pad attached to the mounting plate;
wherein each of the plurality of posts is inserted through one of the plurality of mounting holes thereby mounting the touch pad to the enclosure.

2. The electronic device of claim 1, wherein the enclosure defines an opening, the plurality of mounting posts surrounds the opening.

3. The electronic device of claim 2, wherein a touch-sensitive surface of the touch pad is accessible through the opening of the enclosure.

4. The electronic device of claim 1, wherein each of the plurality of tabs further defines an installation hole communicating with the mounting hole, a diameter of the installation hole is greater than a diameter of the mounting hole, the mounting member is movable between a locked position where each of the plurality of mounting posts is received in the mounting hole and a unlocked position where each of the plurality of mounting posts is received in the installing hole.

5. The electronic device of claim 4, wherein when the mounting member is moved in a first direction, the mounting post slides from the installation hole to the mounting hole, and when the mounting member is moved in a second direction opposite to the first second direction, the mounting post slides from the mounting hole to the installing hole.

6. The electronic device of claim 1, wherein each of the plurality of tabs is substantially rectangular.

7. The electronic device of claim 1, wherein the mounting plate is substantially rectangular.

8. The electronic device of claim 1, wherein a diameter of a top end of mounting post is smaller than a diameter of a bottom end of the mounting post.

9. The electronic device of claim 1, wherein the mounting plate defines a through hole, a portion of a rear surface of the touch pad is exposed through the through hole.

10. A mounting assembly for mounting a touch pad, comprising:
an enclosure;
a plurality of mounting posts protruding from an inner surface of the enclosure; and
a mounting member comprising a mounting plate, a plurality of tabs extending from the mounting plate, each of the plurality of tabs defining a mounting hole, the mounting plate is configured for bonding the plurality of tabs to a touch pad,
wherein each of the plurality of posts is inserted through one of the plurality of mounting holes thereby mounting the touch pad to the enclosure.

11. The mounting assembly of claim 10, wherein the enclosure defines an opening, the plurality of mounting posts surrounds the opening.

12. The mounting assembly of claim 11, wherein the opening is configured for exposing a touch-sensitive surface of the touch pad.

13. The mounting assembly of claim 10, wherein each of the plurality of tabs further defines an installation hole communicating with the mounting hole, a diameter of the installation hole is greater than a diameter of the mounting hole, the mounting member is movable between a locked position where each of the plurality of mounting posts is received in the mounting hole and a unlocked position where each of the plurality of mounting posts is received in the installing hole.

14. The mounting assembly of claim 13, wherein when the mounting member is moved in a first direction, the mounting post slides from the installation hole to the mounting hole, and when the mounting member is moved in a second direction opposite to the first second direction, the mounting post slides from the mounting hole to the installing hole.

15. The mounting assembly of claim 10, wherein each of the plurality of tabs is substantially rectangular.

16. The mounting assembly of claim 10, wherein the mounting plate is substantially rectangular.

17. The mounting assembly of claim 10, wherein a diameter of a top end of mounting post is smaller than a diameter of a bottom end of the mounting post.

18. The mounting assembly of claim 10, wherein the mounting plate defines a through hole configured for exposing a portion of a rear surface of the touch pad.
